(19) United States
(12) Patent Application Publication
(10) Pub. No.: US 2004/0144972 A1
(43) Pub. Date: Jul. 29, 2004

(54) Carbon nanotube circuits with high-kappa dielectrics

(76) Inventors: Hongjie Dai, Sunnyvale, CA (US); Paul C. McIntyre, Sunnyvale, CA (US); Ali Javey, Stanford, CA (US)

Correspondence Address: Crawford Maunu PLLC, Suite 390, 1270 Northland Drive, St. Paul, MN, 55120, US

(21) Appl. No.: 10/679,936

(22) Filed: Oct. 6, 2003

Related U.S. Application Data
(60) Provisional application No. 60/416,326, filed on Oct. 4, 2002.

(51) Int. Cl. H01L 29/06; H01L 31/0328; H01L 31/0336; H01L 31/072; H01L 31/109

(52) U.S. Cl. 257/20

(57) ABSTRACT

Carbon nanotube circuits are implemented with high-κ dielectrics. According to one example embodiment of the present invention, a carbon nanotube circuit includes at least one carbon nanotube with a high-κ dielectric material. In one implementation, a gate electrode is capacitively coupled to the carbon nanotube via the high-κ dielectric material. Voltage applied to the gate electrode is thus capacitively coupled to the carbon nanotube to control, for example, electrical characteristics of the carbon nanotube. With this approach, the carbon nanotube circuit exhibits voltage-controllable characteristics that can be used for a variety of implementations.

### RELATED PATENT DOCUMENTS

This patent document relates to U.S. Provisional Patent Application Serial No. 60/416,326, entitled “High-κ Dielectrics for Advanced Carbon Nanotube Transistors and Logic” and filed on Oct. 4, 2002, to which priority is claimed under 35 U.S.C. §120 for common subject matter.

### FEDERALLY SPONSORED RESEARCH OR DEVELOPMENT

This invention was made with Government support under contract MDA 972-01-1-0035 awarded by the Defense Advanced Research Projects Agency. The U.S. Government has certain rights in this invention.

### FIELD OF THE INVENTION

The present invention relates generally to nanotubes and more particularly to the carbon nanotube approaches involving high-κ (dielectric constant) dielectrics.

### BACKGROUND

Molecular electronics is an emerging area whose goal is to use molecular materials as core device components. Molecular structures are small in size, surpassing structures attainable by top-down lithography, and could therefore be essential to miniaturization. Yet, a wide open question is whether molecular materials could bring about higher device performance than conventional electronic materials, especially for the most basic and widely used device units, such as field effect transistors (FETs).

A small subthreshold swing (S), a parameter key to the scaling of FETs, is desired for low threshold voltage and low power operation for FETs scaled down to small sizes. Within the model for metal-oxide-semiconductor field effect transistors (MOSFET), S is determined by S=ln10 ·[dV_{gs}/d(lnI_{ds})]=(k_{B}T/e)ln10·(1+α), where e is the elementary charge and α depends on capacitances in the device and is ˜0 when the gate capacitance is much higher than other capacitances. The lowest theoretical limit for S is therefore S=(k_{B}T/e)·ln(10)≈60 mV/decade at room temperature. Intense effort has been taken to reach this limit for Si based devices, and new types of transistor schemes have been sought to overcome this barrier.

In some instances, carbon nanotubes have been implemented in gated structures. These carbon nanotubes, including single-walled carbon nanotubes (SWNT), are recently discovered, hollow graphite tubules and are promising as core components or interconnecting wires for electronics and other applications. Rich quantum phenomena have been revealed with SWNTs, from which functional electronic devices can be built. When isolated, individual nanotubes are particularly useful for making microscopic electrical, mechanical, or electromechanical devices.

One hope for SWNTs in electronics devices is its usefulness in providing high carrier mobility, as electrical transport in high quality nanotubes can be ballistic. In terms of gating of nanotubes, the most widely used gate structure has been macroscopic, doped Si substrates as back-gates and thermally grown SiO₂ as gate dielectrics. Recently, several new gate structures have been developed for nanotubes, including bottom aluminum gate with sub-nanometer thick native Al₂O₃ dielectrics, top-gates with ˜15-20 nm thick SiO₂ dielectrics, bottom tungsten gates with SiO₂ dielectrics and electrochemical gate with an aqueous electrolyte solution as dielectrics. These works have obtained progressively improving nanotube transistor characteristics. For instance, the subthreshold swing has reached S˜130 mV/decade for top-gated nanotubes, and S˜80 mV/decade for solution gated SWNTs.

The integration of nanotubes in a variety of applications, however, has been challenging. For example, the implementation of carbon nanotubes in conventional devices, such as transistors, in usable and reliable manner has been difficult. Moreover, improvements in such devices are important to the advancement of their use in a variety of implementations.

The above-mentioned and other difficulties in integrating carbon nanotubes have presented challenges to the implementation of such nanotubes in a variety of applications.

### SUMMARY OF THE INVENTION

The present invention is directed to overcoming the above-mentioned challenges and others related to carbon nanotubes and nanotube devices. The present invention is exemplified in a number of implementations and applications, some of which are summarized below.

According to an example embodiment of the present invention, a capacitive structure includes a carbon nanotube a high-κ dielectric material via which capacitive coupling can be effected, for example, using an electrode. The carbon nanotube and high-κ dielectric material are configured and arranged such that a voltage capacitively coupled to the carbon nanotube via the high-κ dielectric material can be used for controlling current flow in the carbon nanotube.

According to another example embodiment of the present invention, a semiconductor device includes a carbon nanotube between source and drain nodes. A gate electrode is separated from the carbon nanotube by a high-κ dielectric material. The gate is further coupled to circuitry and configured and arranged for applying a signal from the coupled circuitry to the carbon nanotube via the high-κ dielectric material for controlling current flow between the source and drain nodes. With this approach, the semiconductor device may be implemented in connection with a variety of applications, such as for a field-effect transistor (FET) involving computer and/or memory processing and/or access applications.

In another example embodiment of the present invention, a circuit includes a substrate having an insulative layer on a bulk layer and a plurality circuits formed thereon, including at least one of the semiconductor devices discussed above. The carbon nanotube and both source and drain regions are disposed on the insulative layer, with the gate and high-κ dielectric material over the carbon nanotube.

The above summary of the present invention is not intended to describe each illustrated embodiment or every implementation of the present invention. The figures and detailed description that follow more particularly exemplify these embodiments.

### BRIEF DESCRIPTION OF THE DRAWINGS

The invention may be more completely understood in consideration of the detailed description of various embodiments of the invention that follows in connection with the accompanying drawings, in which:

FIG. 1(a) is a side view of a SWNT-FET having a high-κ dielectric material, according to an example embodiment of the present invention;

FIG. 1(b) is a top view scanning electron microscopy (SEM) image of a capacitive structure, according to another example embodiment of the present invention;

FIG. 1(c) is a cross-sectional view of a high-κ dielectric material deposited on a substrate having an insulative layer, according to another example embodiment of the present invention;

FIG. 1(d) is a cross-sectional view of a capacitive structure, according to another example embodiment of the present invention;

FIG. 2(a) is a current-versus-voltage curve for a p-type SWNT-FET, according to another example embodiment of the present invention;

FIG. 2(b) is a current-versus-voltage curve for another p-type SWNT-FET, according to another example embodiment of the present invention;

FIG. 2(c) is another current-versus-voltage curve for a p-type SWNT-FET, according to another example embodiment of the present invention;

FIG. 2(d) shows gate leak current versus top gate voltage for a p-type SWNT-FET, according to another example embodiment of the present invention;

FIG. 3(a) shows a current-versus-voltage curve for an n-type SWNT-FET, according to another example embodiment of the present invention;

FIG. 3(b) shows a current-versus-voltage curve for an n-type SWNT-FET, according to another example embodiment of the present invention;

FIG. 4(a) shows a complementary NOT logic device and transfer characteristics therefor, according to another example embodiment of the present invention; and

FIG. 4(b) shows an OR gate device and characteristics therefor, according to another example embodiment of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

The present invention is believed to be applicable to a variety of different types of devices, and the invention has been found to be particularly suited for carbon nanotubes in connection with high-κ dielectrics. While the present invention is not necessarily limited to such applications, various aspects of the invention may be appreciated through a discussion of various examples using this context.

According to an example embodiment of the present invention, high-κ dielectric materials are integrated into capacitive structures including a carbon nanotube. A high-κ dielectric material is formed on a carbon nanotube and separates the carbon nanotube from a gate electrode, forming the capacitive structure. Opposing ends of the carbon nanotube can then be used, for example, to control electrical connection between circuit nodes with the gate electrode.

In a more particular example embodiment of the present invention, a high-κ (about 25) zirconium oxide (ZrO₂) thin film (about 8 nm thick) is formed on top of individual single-walled carbon nanotubes (SWNT) by atomic layer deposition (ALD). The high-κ-coated SWNTs is implemented as a nanotube field effect transistor (FET, e.g., a ZrO₂/SWNT-FET), with a gate electrode capacitively coupled to the SWNT via the high-κ dielectric. In connection with this example embodiment, it has been discovered that the ALD process affords gate insulators with high capacitance while being chemically benign to nanotubes, which has been found useful for the integration of advanced dielectrics into molecular electronics. In one implementation, voltage gains up to about 60 are obtained for complementary nanotube-based inverters employing this approach. In another implementation, the on-state resistance of the ZrO₂/SWNT FET is about 100-500 kΩ, which is similar to those that did not undergo ZrO₂ ALD.

The transconductance of this carbon-nanotube-based FET reaches about 6000 S/m (normalized by the width of nanotube), exceeding that achieved for silicon devices. In addition, the FET exhibits high carrier mobility, for instance, on the order of about 3000 cm²/Vs. In one implementation, the FET is employed in a complementary inverter and exhibits voltage gains up to about 60.

In one implementation, the carbon nanotube is a p-type nanotube and the device thus forms a p-type transistor that exhibits subthreshold swings of about 70 mV/decade, approaching the room temperature theoretical limit for FETs. The p-type nanotube device exhibits transistor performance parameters of transconductance and carrier mobility that reach about 6000 S/m (12 μS per tube) and about 3000 cm²/Vs respectively.

In another implementation, the length of the gate electrode discussed above is scaled down to tens of nanometers (e.g., less than 100 nanometers). The use of a high-κ dielectric in connection with a carbon nanotube as discussed above is useful in connection with this scaling. High-κ gate insulators afford high capacitance without relying on ultra-small film thickness, thus allowing for efficient charge injection into the channel region (e.g., a portion of the carbon nanotube to which the gate electrode is capacitively coupled) and meanwhile reducing direct tunneling leakage currents.

For general information regarding high-κ films (κ˜20-30 for e.g., ZrO₂ and HfO₂) and for specific information regarding high-κ films that may be implemented in connection with one or more example embodiments herein, reference may be made to the following references: Wilk, G. D., Wallace, R. M. & Anthony, J. M., High-k gate dielectrics: current status and materials properties considerations, J. Appl. Phys. 89, 5243-5275 (2001); Harrop, P. J. & Campell, D. S., Selection of thin film capacitor dielectrics, Thin Solid Films 2, 273-292 (1968); Perkins, C. M., Triplett, B. B., McIntyre, P. C., Saraswat, K. C. & Shero, E., Thermal stability of polycrystalline silicon electrodes on ZrO₂ gate dielectrics, AppL. Phys. Lett. 81, 1417-1419 (2002); and Alternative Gate Dielectrics for Microelectronics, MRS Bull. 27 (March 2002). Each of these references is fully incorporated herein by reference.

In addition, for various implementations, “high-κ” refers to a dielectric constant that is at least about 12 (i.e., above aluminum oxide). Furthermore, the high-κ films implemented in connection with one or more example embodiments can include one or more of a variety of high-κ materials, such as Beryllium oxide, Dysprosium oxide, Erbium oxide, Gadolinium oxide, Hafnium. oxide, Lanthanum oxide (e.g., La₂O₃), Thorium oxide, Uranium oxide, Yttrium oxide and Zirconium oxide (e.g., ZrO₂), or other transition metal oxides, oxides in the Lanthanide series and/or oxides in the Actinide series.

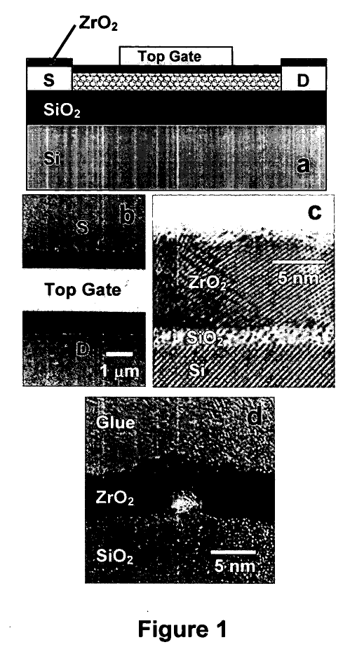

In another example embodiment of the present invention, chemical vapor deposition (CVD) is used to synthesize individual semiconducting SWNTs bridging metal source (S) and drain (D) electrodes (spacing about 3 μm) on SiO₂/Si substrates, for example, as shown in FIGS. 1(a) and 1(b) and discussed further below in the experimental data section. Specifically, FIG. 1(a) shows a side view of a SWNT-FET with a ZrO₂ dielectric layer having a nominal thickness of about 8 nm formed by ALD on top of an array of SWNT FETs (with a common Si back-gate). Local top-gates (2 μm wide) are then patterned and located between the S and D electrodes for each of the transistors. The thickness of thermally grown SiO₂ on the Si substrate is about 500 nm. FIG. 1(b) shows a top view of the SWNT-FET shown in FIG. 1(a) as imaged via scanning electron microscopy (SEM), with the gated length of the nanotube being about 2 microns.

Using the approaches discussed in the previous paragraph, FIG. 1(c) shows a cross-sectional TEM that shows the crystallinity of ZrO₂ film on SiO₂ substrate, and FIG. 1(d) shows coverage of ZrO₂ on SWNTs. Specifically, FIG. 1(c) shows a cross-section transmission electron microscopy (TEM) image of an 8 nm ZrO₂ deposited by ALD on ˜1.4 nm thermally grown SiO₂. FIG. 1(d) shows a TEM image of the cross-section of a SWNT on SiO₂ with conformal coating of 4 nm thick ZrO₂. The circular region at the ZrO₂-SiO₂ interface is the cross section of a nanotube that exhibits light contrast in the TEM.

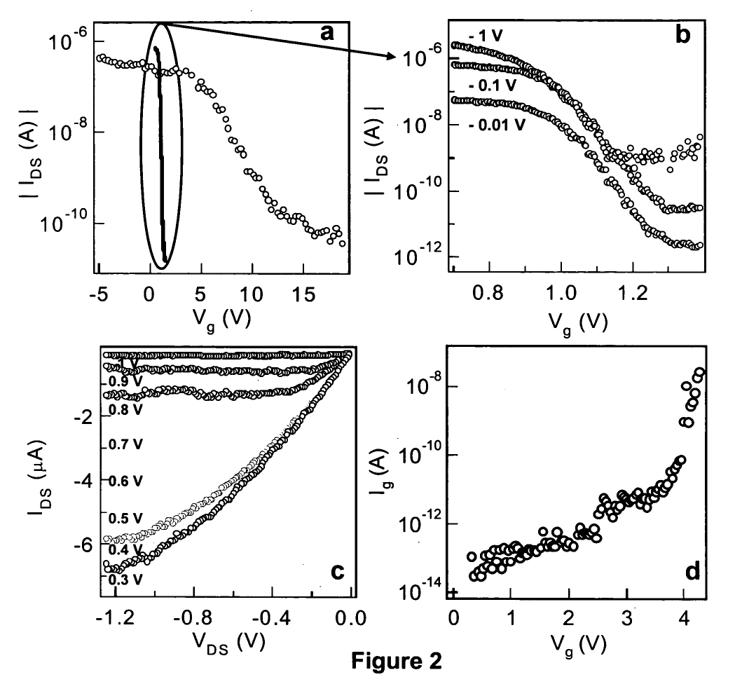

FIG. 2(a) shows current (I_{ds}) vs. gate voltage (V_{gs}) characteristics for an as-made (p-type) SWNT transistor when back-gated through a 500 nm thick SiO₂ layer (curve with circles), and when top-gated through a ZrO₂ dielectric layer (solid curve), in connection with another example embodiment of the present invention. The subthreshold swings S, defined as S=ln10·[dV_{gs}/d(lnI_{ds})], is about 1-2 V/decade. Such I_{ds}−V_{gs} curves can be recorded under V_{ds=-}100 mV with the bottom Si/SiO₂ gate represented by circles and the top-gate/ZrO₂ represented by a solid curve respectively, with the bottom gate being grounded during top-gate operation. For general information regarding subthreshold swing and for specific information regarding devices and implementations to which this and other example embodiments discussed herein may be applied, reference may be made to Sze, S. M., Physics of semiconductor devices, (Wiley, N.Y., 1981), which is fully incorporated herein by reference.

FIG. 2(b) shows current vs. gate voltage characteristics for a SWNT transistor, according to another example embodiment of the present invention. The SWNT transistor has a top-gate and about an 8 nm thick ZrO₂ dielectric between the SWNT and the gate, with S of about 70 mV/decade, as up to five orders of magnitude change in current is observed for a top-gate voltage change of about 0.4 V. Such I_{ds}−V_{gs} curves can be recorded, for example, with the top-gate/ZrO₂ at bias voltages of about V_{ds=-}10 mV, −0.1 V and −1 V, respectively as shown. Subthreshold swings for p-type ZrO₂/SWNT FETs are reproducibly shown in the S=70-100 mV/decade range for various bias voltages Vds=−0.01 to −1 V. The tunneling leak current through the ˜8 nm thick ZrO₂ dielectric layer is negligible in the range of gate voltages of less than or equal to about 3V, as shown in FIG. 2(d).

FIG. 2(c) shows current vs. source-drain bias voltage curves (I_{ds}−V_{ds}) under various gate voltages V_{gs} in steps of 0.1 V for the ZrO₂/SWNT transistors implemented in connection with another example embodiment of the present invention. Such I_{ds}−V_{ds} curves of the FET can be recorded for various top-gate voltages at 0.1 V steps. The shapes of the I_{ds}−V_{ds} curves closely resemble those of conventional p-MOSFETs, exhibiting linear triode regions at low V_{ds}, and saturation regions at higher V_{ds}. In the saturation regions of the I_{ds}−V_{ds} curves, we deduce a transconductance of gₘ, approximated by dI_{ds}/dV_{gs}|_{Vds=-1.2V}=12 μS. Normalized by the width of the nanotube d ˜2 nm, a transconductance of 6000 S/m is obtained. A fair comparison between these nanotube-based FETs and Si based devices is nontrivial due to the quasi one-dimensional nature of SWNTs.

In another implementation, the apparent diameter normalized transconductance of a SWNT-FET device is about 10 times higher than that in conventional p-type crystalline Si. For instance, the effective device width for of the SWNT-FET can be implemented at about twice the nanotube diameter 2 d˜4 nm that is the effective gate-width as the charge distribution on the gate plane spreads over a larger width than the tube diameter. When packing parallel nanotubes for SWNT-FET devices in one implementation, taking the effective width of the devices to be ˜2 d, the transconductance is about 3000 S/m. With this approach, SWNT-FETs can be implemented in applications that benefit from high transconductance, such as transistors and voltage gain applications of transistor-based devices including amplifiers and logic gates.

In another example embodiment of the present invention, a ZrO₂/SWNT FET is implemented as a quasi one-dimensional SWNT channel, with the electrostatic gate coupling capacitance having a logarithmic dependence on the thickness of the dielectric layer, C_{g}_{_{—}}_{ZrO2}=2πεε₀L/[cos h⁻¹(h/r)]≈2πεε₀L/ln(2 h/r) where the ZrO₂ dielectric constant ε˜25 and thickness h=8 nm. For a nanotube with gated length of L˜2 μm and radius r˜1 nm, the electrostatic capacitance C_{g}_{_{—}}_{ZrO2}=1.1 fF (unit length capacitance 5 pF/cm). This capacitance is slightly higher than the quantum capacitance of the 2 μm gated nanotube C_{gs}_{_{—}}_{Q =}0.8 fF (unit length quantum capacitance 4 pF/cm). The total gate capacitance is then C_{gs}=(C_{g}_{_{—}}_{ZrO2}C_{g}_{_{—}}_{Q})/(C_{g}_{_{—}}_{ZrO2}+C_{g}_{_{—}}_{Q})=0.46 fF.

In the low bias linear triode regions of the I_{ds}−V_{ds}, curves, the hole mobility μₕ can be deduced from g_{ds}=I_{ds}/V_{ds}=2K(V_{gs}−V_{T}), where g_{ds} is the zero bias conductance, K is the conductivity parameter given by K=μₕC_{gs}/2 L², and V_{T}=1 V is the threshold gate voltage for the device. Alternatively, the carrier mobility can be derived from the saturation regions of the I_{ds}−V_{ds} curve by I_{ds}=K(V_{gs}−V_{T}). Both methods yield μₕ˜3000 cm²/Vs, which is about 8 times higher than that in p-type bulk crystalline Si (˜450 cm²/Vs). Further, in an actual Si MOSFET, the hole-mobility is about half of that of bulk Si due to surface roughness scattering.

In another example embodiment of the present invention, the top gate of a ZrO₂/SWNT-FET covers a ˜2 μm long segment of the SWNT (e.g., instead of the full length between the source and drain). The subthreshold swing for this ZrO₂/SWNT-FET is S˜70 mV/decade, which can be, for example, superior to devices with bottom gates and Al₂0₃ and SiO₂ dielectrics (S˜180 mV/decade and 400 mV/decade respectively), and to those with top-gates through SiO₂ (S˜130 mV/decade). In aqueous electrolyte solutions, the high dielectric constant of water (κ˜80) affords subthreshold swings of S˜80 mV/decade. The diameter-normalized transconductance of 6000 S/m for this ZrO₂/SWNT FET is the highest among solid state gated tube devices. Transconductance normalized in the same manner for top-gated SiO₂(15 nm)/SWNT FETs is ˜2300 S/m, and 300 S/m for bottom gated Al₂O₃/SWNT FETs.

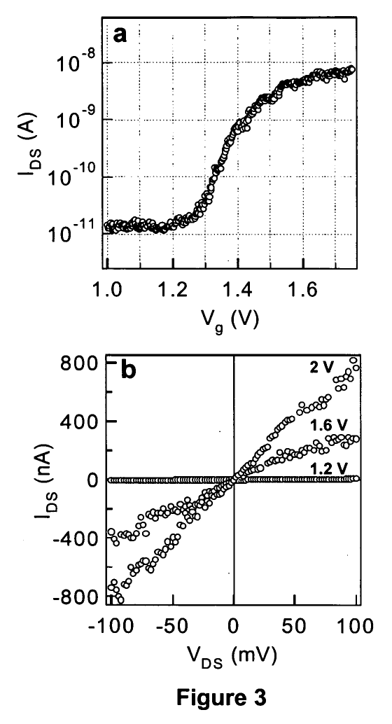

In another example embodiment of the present invention, an n-type FET is manufactured using a high-κ-coated carbon nanotube as discussed above. In one implementation, as-made p-type ZrO₂/SWNT FETs are converted to n-type transistors by heating in hydrogen at about 400 ° C. for 1 h. FIGS. 3(a) and 3(b) show the characteristics of an n-type ZrO₂/SWNT FET (n-FET) obtained in this way.

FIGS. 3(a) and 3(b) show approaches to an n-type FET having a subthreshold swing of ˜90-100 mV/decade, with a transconductance of ˜600 S/m, and electron mobility of μ_{n˜}1000 cm²/Vs. Such an I_{ds}−V_{gs} curve can be recorded under a V_{ds}=10 mV bias. FIG. 3(b) shows I_{ds}−V_{ds} curves for the device at various top-gate voltages. The n-type devices are obtained by annealing in hydrogen, and recover to p-type after exposure to air for about one day.

SWNTs employed in the SWNT-FETs discussed herein are converted to n-type using a variety of approaches, depending upon the implementation. In some implementations, one or more of the following doping approaches are used: direct charge transfer between nanotubes and adsorbed O₂, doping by S/D metal due to work-function mismatch adsorbed O₂ on metal affecting the S/D metal work-function. After the ALD ZrO₂ deposition on the nanotubes, the I_{ds}−V_{gs} curves shift towards the more positive V_{gs} side by ˜10 V (V_{T}˜10 V with backgate), signaling significant additional hole-doping to the SWNTs. This doping may be effected, for instance, by oxidative species or charge traps in ZrO₂.

In connection with another example embodiment, it has been discovered that ALD of ZrO₂ using a ZrCl₄ precursor leaves up to about 1 atom % of chloride ions, which could cause hole-doping or act as charge traps. This contributes to the normally ON operation for our p-FETs (depletion mode) with relatively high top-gate threshold voltages of V_{T}˜1V (corresponding to a p-doping fraction of f˜0.01 estimated from capacitance and V_{T}). Annealing in hydrogen is used to removed the oxygen p-doping source, resulting in a relatively high voltage (V_{T}˜1.2V) is now needed to turn on the resulting n-FET (in enhancement-mode).

In another example embodiment, efficient n-doping in the top-gated tube-section under V_{gs}>V_{T} transmits to an un-gated section of the nanotube due to long screening lengths in nanotubes. This approach, combined with metal-tube workfunction mismatch (S/D Mo metal workfunction˜4.6 eV; nanotube˜5 eV) effects, renders the un-gated section slightly n-type. In one implementation, the partial-gating structure is coupled with direct doping of the un-gated sections either chemically or by using the back-gate, thereby reducing the ON state resistance of the SWNT-FET.

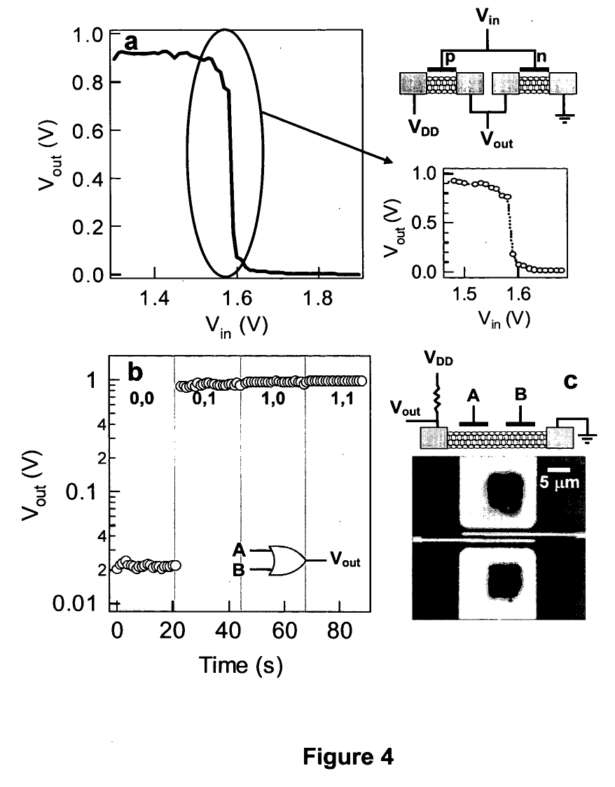

In another example embodiment of the present invention, both p- and n-type SWNT-FETs are implemented, for instance, to construct complementary electronics. FIG. 4(a) shows one such complementary electronics implementation involving a NOT logic gate (i.e., an inverter) formed by connecting a p- and n-type ZrO₂/SWNT FET. This implementation, operated at V_{DD}=1 V, exhibits a relatively high voltage gain. In the inversion region of the transfer characteristics, the output voltage changes by about 0.6 V upon an input voltage change of about 10 mV, giving rise to a voltage gain up to β=ΔVₒᵤₜ/ΔVᵢₙ˜60. The relatively high transconductance discussed above has been useful, for example, in achieving such a relatively high voltage gain.

Referring again to FIG. 4(a), the right panel shows the schematic device structure and a zoom-in of the transfer characteristics in the inversion region, with the operating input voltage range for the inverter being higher than that of the output. In some implementations, amplifiers are used in conjunction with the ZrO₂/SWNT inverter to realize high voltage gain. The high threshold voltages for the p- and n-FETs are responsible for the asymmetric transfer characteristics, and can be adjusted by controlling the bulk-length nanotube doping.

In another example embodiment of the present invention, multiple local gate electrodes are fabricated on ZrO₂ dielectrics and SWNTs, which readily allows for diverse electronic functions based on individual nanotubes. FIG. 4(b) shows one such approach involving an OR gate obtained with two gate electrodes fabricated on ZrO₂ and a p-type SWNT in conjunction with a 10 MΩ resistor. The right panel shows the schematic and an optical image of the device, with the operating voltage being V_{DD}=1 V and the inputs for the two gates (A and B) being 2 V for state 1 and 0 V for state 0. The OR function comes about since the output voltage is low when both gates are at low voltages so that the nanotube channel is in the on-state. When one or both gates are at high voltages, the nanotube channel is electrically shut off, resulting in a high output voltage defined by the input.

### Experimental Data

The following example experimental embodiments and embodiments discussed in connection with the figures may be implemented in connection with one or more example embodiments of the present invention, including those discussed hereinabove.

SWNT FETs with Top-Gates and ZrO₂ Gate Dielectrics:

The substrates used were doped Si wafers with 500 nm thick SiO₂ layers, and the doped Si can be used as the usual back-gate. We first patterned Mo source (S)—drain (D) electrode arrays on a substrate, followed by catalyst patterning on top of the electrodes and CVD growth of SWNTs to bridge the pre-formed source and drain. After growth, atomic force microscopy (AFM) was used to identify devices in the array with S/D electrodes connected by individual SWNTs. Conductance vs. back-gate measurements were then used to identify individual semiconducting nanotubes. A ZrO₂ film of 8 nm nominal thickness was deposited onto the sample by ALD using ZrCl₄ precursor and H₂O oxidizer in a high purity N₂ carrier gas. Films were deposited in a load-locked ALD research reactor with base pressure of 10⁻⁸ Torr and a process pressure of 0.5 Torr. The ZrO₂ ALD process was performed at 300° C. with alternating pulses (1-2 s duration) of the precursor and oxidizer. Each precursor/oxidizer pulse cycle resulted in the deposition of ˜0.6 Å of ZrO₂ onto SiO₂. Cross-wafer ellipsometry measurements (calibrated by cross-sectional TEM) were used to confirm the film thickness and thickness uniformity of the ZrO₂ by ALD. Standard electron beam lithography and liftoff processes were then used to pattern top-gates (Ti/Au) on the deposited ZrO₂ film between the S-D electrodes.

Cross-Sectional TEM:

Transmission electron microscopy was performed in a Philips CM20 microscope operated at an accelerating voltage of 200 kV. Thin foil specimens of SiO₂ substrates with ALD ZrO₂ (FIG. 1c) were prepared by typical mechanical polishing steps including cutting the substrate into half, bonding of the two pieces face-to-face by glue and thinning the cross-section followed by a brief argon ion milling to perforation. Previous studies of ALD-ZrO₂ gate dielectric layers deposited on to oxidized Si surfaces have shown that the films are polycrystalline and exhibit the tetragonal zirconia crystal structure. These results are consistent with TEM images obtained from the present zirconia dielectrics. For cross-sectional TEM of ZrO₂ coated SWNTs on SiO₂ (FIG. 1d), SWNTs were first grown on the SiO₂ substrate with discrete catalytic Fe₂O₃ nanoparticles deposited on the surface. The number of SWNTs in a 10×10 μm² is about 20 measured by AFM. ZrO₂ was then deposited on the sample, followed by TEM specimen preparation in the same way as the SiO₂/ZrO₂ samples. Note the catalytic nanoparticles stayed at the one of the ends of each SWNT. Therefore, the SiO₂ substrate was clean, containing only nanotubes on the surface. Circular structures of 1-3 nm diameter and with an image contrast lighter than the surrounding SiO₂ and ZrO₂ layers were frequently observed in cross-sectional TEM (FIG. 1d) imaging of the SWNT samples, and were absent with SiO₂/ZrO₂ samples without SWNTs grown on the substrate. These structures were attributed to nanotubes observed in varying degrees of oblique cross-section, with the nanometer-scale region of lightest contrast corresponding to the nanotube.

The various embodiments described above are provided by way of illustration only and should not be construed to limit the invention. Based on the above discussion and illustrations, those skilled in the art will readily recognize that various modifications and changes may be made to the present invention without strictly following the exemplary embodiments and applications illustrated and described herein. Such changes may include using other arrangements and substrate materials. For instance, various high-κ materials may be implemented in connection with the devices discussed and shown. Such modifications and changes do not depart from the true spirit and scope of the present invention.

What is claimed is:

1. A semiconductor device comprising:
a high-κ dielectric material disposed on a carbon nanotube.

2. A semiconductor device comprising:
a carbon nanotube;
an electrode; and
a high-κ dielectric material disposed between the carbon nanotube and the electrode.

3. The semiconductor device of claim 2, further comprising an insulative substrate, wherein the carbon nanotube is disposed on the insulative substrate.

4. The semiconductor device of claim 2, further comprising circuit nodes at opposing ends of the carbon nanotube.

5. The semiconductor device of claim 4, wherein the circuit nodes are source/drain regions and wherein the carbon nanotube is a semiconducting channel between the source/drain regions.

6. The semiconductor device of claim 5, wherein the electrode is configured and arranged with the carbon nanotube and the high-κ dielectric material for capacitively coupling a signal to the carbon nanotube for controlling current flow between the source/drain regions.

7. The semiconductor device of claim 2, wherein the high-κ dielectric material has a thickness of about 8 nanometers.

8. The semiconductor device of claim 2, wherein the high-κ dielectric material includes ZrO₂.

9. The semiconductor device of claim 2, wherein the carbon nanotube is p-type.

10. The semiconductor device of claim 2, wherein the carbon nanotube is n-type.

11. An electronic circuit comprising:
a substrate having an insulative layer over a bulk layer;
a source region and a drain region disposed on the insulative layer;
a carbon nanotube disposed on the insulative layer and extending from the source region to the drain region;
a high-κ dielectric material on the carbon nanotube; and
an electrode on the high-κ dielectric material and adapted for capacitively coupling to the carbon nanotube via the high-κ dielectric material.

12. An electronic circuit comprising:
a substrate having a gate disposed therein;
a high-κ dielectric material on the gate;
a carbon nanotube on the high-κ dielectric material and extending between two circuit nodes; and
wherein the gate is configured and arranged for capacitively coupling to the carbon nanotube via the high-κ dielectric material for controlling current flow between the two circuit nodes.

13. A field-effect transistor comprising:
first and second source/drain regions;
a carbon nanotube extending between the first and second source/drain regions;
a gate electrode;
a high-κ dielectric material between the carbon nanotube and the gate electrode; and
wherein the FET is configured and arranged for passing current between the first and second source/drain regions via the carbon nanotube in response to a voltage applied to the gate electrode and capacitively coupled to the carbon nanotube via the high-κ dielectric material.

14. The field-effect transistor of claim 13, wherein the gate electrode is about twice as wide as the diameter of the carbon nanotube, the width being in a direction substantially perpendicular to the carbon nanotube.

15. A field-effect memory circuit comprising:
first and second source/drain regions;
a carbon nanotube extending between the first and second source/drain regions;
a gate electrode;
a high-κ dielectric material between the carbon nanotube and the gate electrode; and
wherein the carbon nanotube is configured and arranged for passing current between the first and second source/drain regions in response to a voltage applied to the gate electrode and capacitively coupled to the carbon nanotube via the high-κ dielectric material for accessing circuitry coupled to one of the first and second source/drain regions, current passing and current blocking states of the carbon nanotube defining memory conditions of the memory circuit.

16. A field-effect computer processor comprising:
first and second source/drain regions;
a carbon nanotube extending between the first and second source/drain regions;
a gate electrode;
a high-κ dielectric material between the carbon nanotube and the gate electrode; and
wherein the carbon nanotube is configured and arranged for passing current between the first and second source/drain regions in response to a voltage applied to the gate electrode and capacitively coupled to the carbon nanotube via the high-κ dielectric material for accessing circuitry coupled to one of the first and second source/drain regions, current passing and current blocking states of the carbon nanotube defining processing characteristics of the computer processor.

17. A field-effect logic circuit comprising:
first and second source/drain regions;
a carbon nanotube extending between the first and second source/drain regions;
a gate electrode;
a high-κ dielectric material between the carbon nanotube and the gate electrode; and
wherein the carbon nanotube is configured and arranged for passing current between the first and second source/drain regions in response to a voltage applied to the gate electrode and capacitively coupled to the carbon nanotube via the high-κ dielectric material for accessing circuitry coupled to one of the first and second source/drain regions, a current-passing and current blocking state of the carbon nanotube defining logical states.

18. A method for manufacturing a semiconductor device, the method comprising:
depositing a high-κ dielectric material having a thickness of about 8 nanometers on a carbon nanotube; and
forming an electrode, the high-κ dielectric material separating the electrode from the carbon nanotube.

19. The method of claim 18, wherein depositing a high-κ dielectric material includes using atomic layer deposition.

20. The method of claim 18, further comprising:
converting the carbon nanotube from p-type to n-type.

21. The method of claim 20, wherein converting the carbon nanotube from p-type to n-type includes heating the carbon nanotube in molecular hydrogen.
